(19) United States
(12) Patent Application Publication
(10) Pub. No.: US 2006/0034399 A1
(43) Pub. Date: Feb. 16, 2006

(54) Decoding apparatus and communication system receiver

(75) Inventor: Yukiteru Murao, Yokosuka-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/250,418

(22) Filed: Oct. 17, 2005

(30) Foreign Application Priority Data
Apr. 21, 2004 (JP) 2004-125949

(51) Int. Cl. H03D 1/00

(52) U.S. Cl. 375/341

(57) ABSTRACT

A decoding apparatus and communication system receiver are provided that enable reception performance to be improved in a packet communication system in which the HARQ method is used. In a receiver in a communication system and a decoding apparatus of this receiver there are provided a reception quality measuring apparatus 6, a weighting apparatus 700, and a data generation apparatus 7. Reception quality measuring apparatus 6 measures reception qualities Q1 and Q2 of a first receive data sequence Pr1 that failed to be decoded and a second receive data sequence Pr2 retransmitted based on a Hybrid Automatic Repeat Request (HARQ). Weighting apparatus 700 compares measured reception qualities Q1 and Q2, performs high weighting for the one with the higher reception quality, and performs low weighting for the one with the lower reception quality. Data generation apparatus 7 generates a decoding data sequence Pd in accordance with the weighting based on weighted first receive data sequence Pr1 and second receive data sequence Pr2.

### BACKGROUND OF THE INVENTION

1. Field of the Invention

The present invention relates to a decoding apparatus and communication system receiver, and more particularly to a decoding apparatus and communication system receiver used for packet communication in a digital communication system.

2. Description of the Related Art

The Hybrid Automatic Repeat Request (HARQ) method has been put into actual use in packet communication systems (see, for example, Unexamined Japanese Patent Publication No. 2003-179582). An HARQ is sent from a receiver to a transmitter in the event of a Cyclic Redundancy Check (CRC) error that prevents the receiver from decoding packet communication data due to radio transmission path, high-frequency (RF), or other noise.

After receiving an HARQ, the transmitter transmits the packet communication data to the receiver again. Packet communication data retransmitted based on an HARQ is transmitted in a different data sequence from the packet communication data first transmitted.

The actual packet communication data transmission procedure is as follows. First, the transmitter prepares a transmit data sequence such as {P(0), P(1), P(2)}, for example, as packet communication data, and initially transmits a first transmit data sequence {P(0), P(1)}. Here, P(k) is a 0 or 1 transmit data sequence. If this transmitted packet communication data cannot be decoded correctly by the receiver, the receiver sends an HARQ to the transmitter. On receiving the HARQ, the transmitter next retransmits a second transmit data sequence {P(0), P(2)}.

In the receiver, a decoding data sequence {Pd(0), Pd(1), Pd(2)} is generated based on a first receive data sequence {Pr1(0), Pr1(1)} whereby initial first transmit data sequence {P(0), P(1)} was received and a second receive data sequence {Pr2(0), Pr2(2)} whereby retransmission second transmit data sequence {P(0), P(2)} was received, and this decoding data sequence Pd is decoded. Here, Pd(k) is a decoding data sequence that has a likelihood. In first receive data sequence Pr1(0) and second receive data sequence Pr2(0), the transmit data sequences are the same but the reception statuses of the receive data sequences are different, and therefore the likelihoods of the two are different. The receiver generates a decoding data sequence taking overlapping receive data sequences Pr1(0) and Pr2(0) from among first receive data sequence {Pr1(0), Pr1(1)} received initially and second receive data sequence {Pr2(0), Pr2(2)} received by retransmission as the likelihood addition result (Pr1(0)+Pr2(0)), and this decoding data sequence is decoded.

However, the following point is not taken into consideration in the above-described radio communication system receiver. When an HARQ is transmitted from the receiver, the first receive data sequence contains an error of a level that does not allow correct decoding. As a decoding data sequence is generated by combining this first receive data sequence and a second receive data sequence that may not contain an error and may be correct, there is a possibility of the decoding data sequence being destroyed. That is to say, there is a possibility of not being able to correctly decode a second receive data sequence retransmitted based on an HARQ, lowering the reception performance of the receiver.

### SUMMARY OF THE INVENTION

It is an object of the present invention to provide a decoding apparatus and communication system receiver that enable reception performance to be improved in a packet communication system in which the HARQ method is used.

According to an aspect of the invention, a decoding apparatus is equipped with a reception quality measuring section that measures the reception quality of a first receive data sequence that failed to be decoded and a second receive data sequence retransmitted based on an automatic repeat request; a weighting section that compares the reception qualities of the first receive data sequence and the second receive data sequence, performs high weighting for the one with the higher reception quality, and performs low weighting for the one with the lower reception quality; and a data generation section that generates a decoding data sequence in accordance with weighting based on the weighted first receive data sequence and second receive data sequence.

According to another aspect of the invention, a decoding apparatus is equipped with a reception quality measuring section that measures the reception quality of a first receive data sequence that failed to be decoded and a second receive data sequence retransmitted based on an automatic repeat request; and a data generation section that generates a decoding data sequence based on the first receive data sequence and second receive data sequence; wherein the data generation section has a data generation computation section in which are installed by condition a plurality of computational circuits that generate a decoding data sequence based on the first receive data sequence and the second receive data sequence; and a scenario deciding section that decides on a scenario for selecting one or another computational circuit of the data generation computation section based on the reception quality.

According to still another aspect of the invention, a communication system receiver has a decoding apparatus that is equipped with a reception quality measuring section that measures the reception quality of a first receive data sequence that failed to be decoded and a second receive data sequence retransmitted based on an automatic repeat request; a weighting section that compares the reception qualities of the first receive data sequence and the second receive data sequence, performs high weighting for the one with the higher reception quality, and performs low weighting for the one with the lower reception quality; and a data generation section that generates a decoding data sequence in accordance with weighting based on the weighted first receive data sequence and second receive data sequence.

### BRIEF DESCRIPTION OF THE DRAWINGS

The above and other objects and features of the invention will appear more fully hereinafter from a consideration of the following description taken in conjunction with the accompanying drawing wherein one example is illustrated by way of example, in which:

FIG. 1 is a block diagram showing the configuration of a receiver of a radio communication system according to Embodiment 1 of the present invention;

FIG. 2 is a structural diagram of a radio communication system receiver according to Embodiment 1 of the present invention;

FIG. 3 is a drawing showing the flow of packet communication data in the radio communication system shown in FIG. 2;

FIG. 4 is a sequence diagram showing the packet communication data decoding processing method in the receiver shown in FIG. 1; and

FIG. 5 is a block diagram showing the configuration of a receiver of a radio communication system according to Embodiment 2 of the present invention.

### DESCRIPTION OF THE PREFERRED EMBODIMENTS

The gist of the present invention is that the reception quality of data is measured, a data likelihood is decided according to this measured reception quality, and decoding data is generated according to this likelihood. Here, at least channel quality (Signal to Noise Ratio (SNR)), Bit Error Rate (BER), and so forth, are included in reception quality. Specifically, channel quality A (SNR(A)), for example, of first receive data Pr1 and channel quality B (SNR(B)) of second receive data Pr2 are measured, and if the latter channel quality B is higher than the former channel quality A (SNR(A)<SNR(B)), decoding data (pre-decoding data) Pd is generated by setting second receive data Pr2 for which channel quality B was obtained to a high likelihood (Pd=Pr2), and using this second receive data Pr2 preferentially. As there is a high probability that many errors are contained in channel quality A first receive data Pr1, its likelihood is low. In an embodiment of the present invention, decoding data Pd can be expressed by the following equation in order to increase the degree of freedom. In the following equation, W1 and W2 are weighting coefficients. Weighting coefficients W are decided by means of the channel quality, bit error rate, and so forth.
Pd=W1*Pr1+W2*Pr2

With reference now to the accompanying drawings, preferred embodiments of the present invention will be explained in detail below.

### Embodiment 1

[Configuration of Radio Communication System and Receiver Equipped with Decoding Apparatus]

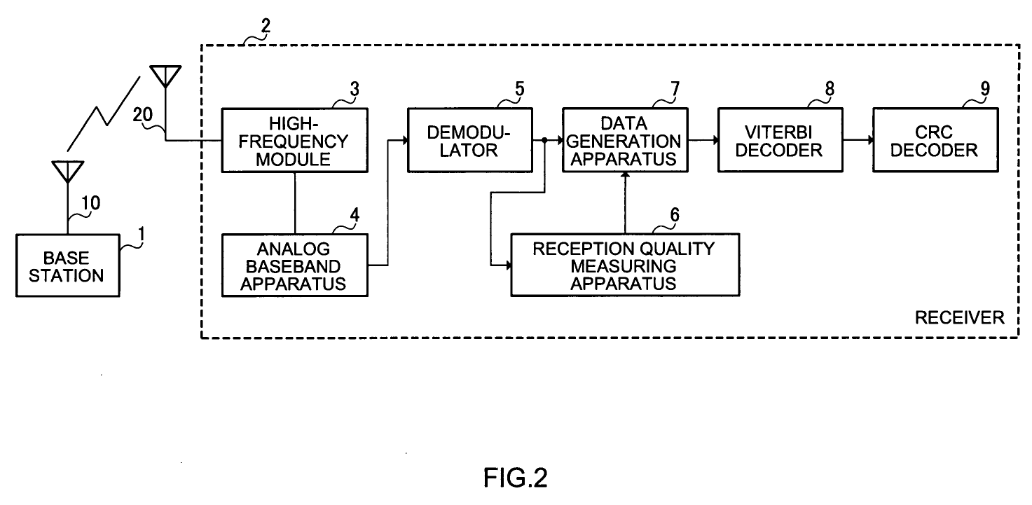

A radio communication system that uses an HARQ method according to an embodiment of the present invention is constructed with the provision of a base station 1 and a receiver 2 as shown in FIG. 2. Packet communication data is transmitted from a transmitting antenna 10 of base station 1, and is received by a receiving antenna 20 of receiver 2.

As shown in FIG. 2, receiver 2 is equipped with a reception quality measuring apparatus (reception quality measuring section) 6 that measures the reception quality Q1 of a first receive data sequence Pr1 that failed to be decoded and the reception quality Q2 of a second receive data sequence Pr2 retransmitted based on an HARQ; a weighting apparatus (weighting section) 700 that compares reception quality Q1 of first receive data sequence Pr1 and reception quality Q2 of second receive data sequence Pr2, performs high weighting for the one with the higher reception quality, and performs low weighting for the one with the lower reception quality; and a data generation apparatus (data generation section) 7 that generates a decoding data sequence (pre-decoding data sequence) Pd in accordance with weighting based on weighted first receive data sequence Pr1 and second receive data sequence Pr2. In addition, as shown in FIG. 2, receiver 2 is equipped with a receiving antenna 20 that receives packet communication data from base station 1, a high-frequency module 3, an analog baseband apparatus (ABB) 4, a demodulator 5, a Viterbi decoder 8, and a CRC decoder 9.

In receiver 2, a k'th receive data sequence Prk (where k is a positive number greater than 2) is additionally received based on an HARQ, reception quality measuring apparatus (reception quality measuring section) 6 measures reception quality Qk of k'th receive data sequence Prk, weighting apparatus 700 performs weighting on k'th receive data sequence Prk based on the measurement result, and data generation apparatus 7 generates decoding data sequence Pd based on weighted k'th receive data sequence Prk.

After being converted from analog to digital signals by demodulator 5, first receive data sequence Pr1, second receive data sequence Pr2, and k'th receive data sequence Prk are input both to reception quality measuring apparatus 6 and to data generation apparatus 7.

Reception quality Q measurement methods that can be used in practice by reception quality measuring apparatus 6 are a method whereby channel quality is estimated from a training sequence known signal included in each of first receive data sequence Pr1 through k'th receive data sequence Prk, and a method whereby Viterbi decoding processing or turbo decoding processing is performed on each of first receive data sequence Pr1 through k'th receive data sequence Prk, and the bit error rate is measured from the data sequence resulting from decoding the generated received signal. Measurement of RXQUAL or measurement of MeanBEP can also be used as the reception quality Q measurement method in reception quality measuring apparatus 6.

In Embodiment 1, weighting apparatus 700 is located inside data generation apparatus 7, and is equipped with a coefficient deciding apparatus (coefficient deciding section) 701 that decides weighting coefficient W according to reception quality Q measured by reception quality measuring apparatus 6; and multipliers 702 through 704 that weight first receive data sequence Pr1, second receive data sequence Pr2, and k'th receive data sequence Prk respectively according to weighting coefficient W.

To be more specific, in weighting apparatus 700, weighting coefficient W1 is decided by coefficient deciding apparatus 701 according to reception quality Q1 of first receive data sequence Pr1 measured by reception quality measuring apparatus 6, and weighting corresponding to weighting coefficient W1 is performed on first receive data sequence Pr1 by multiplier 702 based on first receive data sequence Pr1 and weighting coefficient W1. Similarly, weighting coefficient W2 is decided by coefficient deciding apparatus 701 according to reception quality Q2 of second receive data sequence Pr2 measured by reception quality measuring apparatus 6, and weighting corresponding to weighting coefficient W2 is performed on second receive data sequence Pr2 by multiplier 703 based on second receive data sequence Pr2 and weighting coefficient W2. In the same way, weighting coefficient Wk is decided by coefficient deciding apparatus 701 according to reception quality Qk of k'th receive data sequence Prk measured by reception quality measuring apparatus 6, and weighting corresponding to weighting coefficient Wk is performed on k'th receive data sequence Prk by multiplier 704 based on k'th receive data sequence Prk and weighting coefficient Wk.

In Embodiment 1, multipliers 702 through 704 that combine a weighting coefficient with a receive data sequence are used in weighting apparatus 700, but the present invention is not limited to this, and computing elements, adders or the like can be used, for example.

Data generation apparatus 7 is equipped with weighting apparatus 700 and an adder 710 that adds together first receive data sequence Pr1, second receive data sequence Pr2, and k'th receive data sequence Prk weighted by weighting apparatus 700, and generates decoding data sequence Pd.

### Operation of Radio Communication System and Receiver

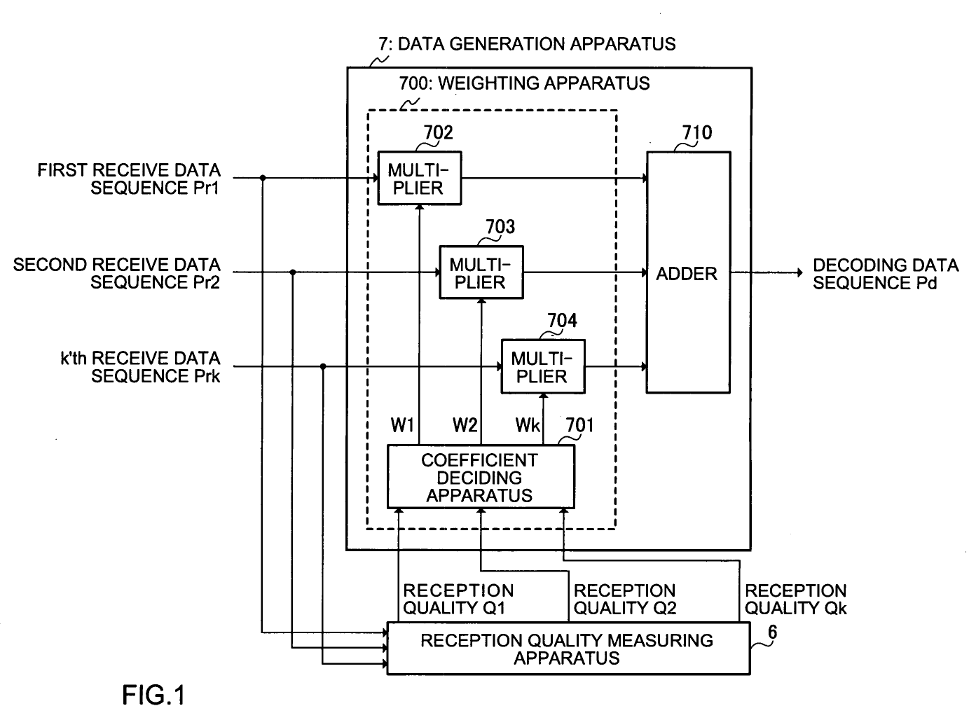

The operation of the radio communication system and receiver will now be described, using FIG. 1 through FIG.4.

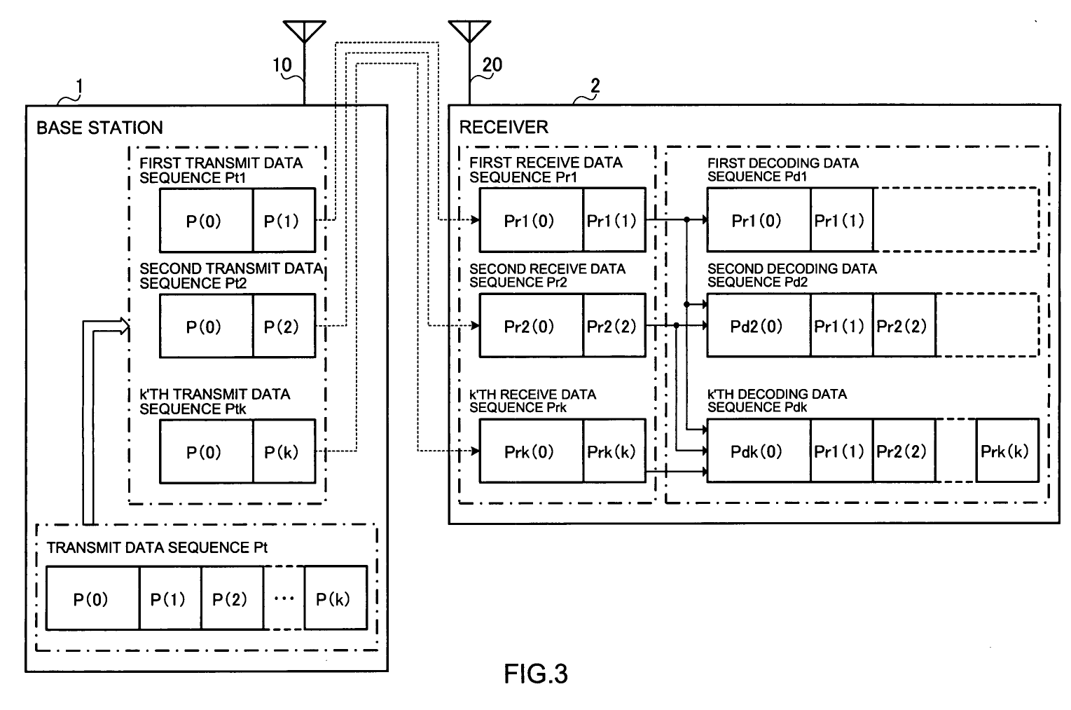

First, a transmit data sequence (coding data sequence) Pt {P(0), P(1), . . . , P(k)} is generated in base station (transmitter) 1, as shown in FIG. 2 and FIG. 3. Transmit data sequence Pt actually transmitted from base station 1 is generated by combining a plurality of data sequences P(i). Here, a first transmit data sequence Pt1 {P(0), P(1)}, second transmit data sequence Pt2 {P(0), P(2)}, . . . , k'th transmit data sequence Ptk {P(0), P(k)} are generated as transmit data sequence Pt. Base station 1 first transmits first transmit data sequence Pt1 {P(0) P(1)} from transmitting antenna 10.

This first transmit data sequence Pt1 is received by receiver 2 via receiving antenna 20. Effects of transmission path noise and receiver 2 noise are sustained, and first transmit data sequence Pt1 is received in receiver 2 as first receive data sequence Pr1 {Pr1(0), Pr1(1)}. This first receive data sequence Pr1 is input to data generation apparatus 7 via high-frequency module 3, analog baseband apparatus 4, and demodulator 5. In data generation apparatus 7, a first decoding data sequence Pd1 {Pr1(0), Pr1(1)} is generated based on first receive data sequence Pr1. In Embodiment 1, data generation apparatus 7 outputs first receive data sequence Pr1 directly as first decoding data sequence Pd1.

This first decoding data sequence Pd1 is decoded by Viterbi decoder 8 shown in FIG. 2, and a cyclic redundancy check (CRC) is performed on this decoded packet communication data by CRC decoder 9. If the result of the cyclic redundancy check is that the packet communication data has not been decoded correctly and an error has occurred, receiver 2 sends an HARQ to transmitter 1.

Based on the HARQ, base station 1 transmits second transmit data sequence Pt2 {P(0), P(2)} from transmitting antenna 10.

This second transmit data sequence Pt2 is received by receiver 2 via receiving antenna 20. Effects of transmission path noise and receiver 2 noise are sustained, and second transmit data sequence Pt2 is received in receiver 2 as second receive data sequence Pr2 {Pr2(0), Pr2(2)}.

Second receive data sequence Pr2 is input to data generation apparatus 7, and is also input to reception quality measuring apparatus 6. Although not shown in FIG. 1 or FIG. 2, in Embodiment 1, buffer memory (for example, Random Access Memory) is installed in a stage prior to data generation apparatus 7 and reception quality measuring apparatus 6. First receive data sequence Pr1 is already stored in this buffer memory. Therefore, first receive data sequence Pr1 is also input to data generation apparatus 7 and reception quality measuring apparatus 6 together with second receive data sequence Pr2. In reception quality measuring apparatus 6, reception quality Q1 of first receive data sequence Pr1 is measured, and reception quality Q2 of second receive data sequence Pr2 is measured, as shown in FIG. 1.

Reception quality Q1 and reception quality Q2 measured by reception quality measuring apparatus 6 are output to coefficient deciding apparatus 701 of weighting apparatus 700 installed in data generation apparatus 7. In coefficient deciding apparatus 701, reception quality Q1 and reception quality Q2 are compared, a high weighting coefficient is set for the higher reception quality, and a low weighting coefficient is set for the lower reception quality. Here, it is assumed that reception quality Q1 of first receive data sequence Pr1 is higher than reception quality Q2 of second receive data sequence Pr2, and a low weighting coefficient W1 is set for reception quality Q1 while a high weighting coefficient W2 is set for reception quality Q2.

As shown in FIG. 1, in weighting apparatus 700, first receive data sequence Pr1 input to data generation apparatus 7 is multiplied by weighting coefficient W1 output from coefficient deciding apparatus 701 by means of multiplier 702. Similarly, in weighting apparatus 700, second receive data sequence Pr2 input to data generation apparatus 7 is multiplied by weighting coefficient W2 output from coefficient deciding apparatus 701 by means of multiplier 703.

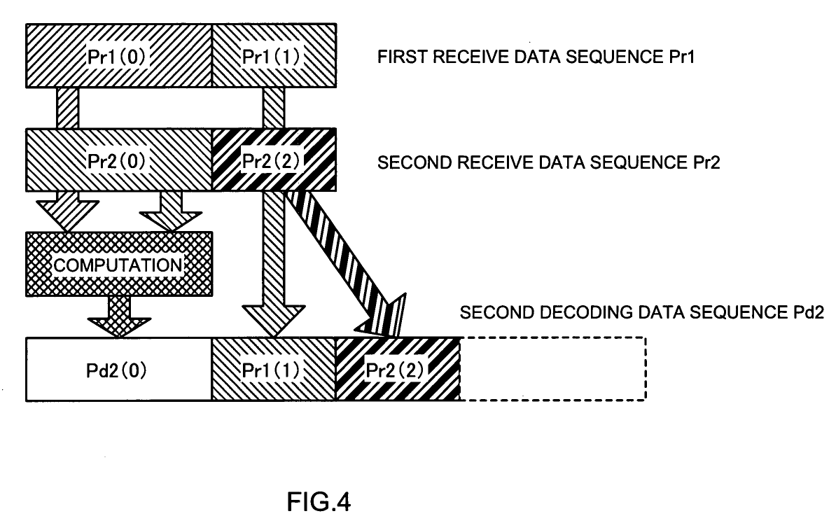

First receive data sequence Pr1 and second receive data sequence Pr2 weighted by weighting apparatus 700 are added together by adder 710 of data generation apparatus 7 shown in FIG. 1. As shown in FIG. 3 and FIG. 4, in adder 710 first receive data sequence Pr1 {Pr1(0)} and second receive data sequence Pr2 {Pr2(0)} are combined in accordance with their weighting, and unweighted first receive data sequence Pr1 {Pr1(1)} and second receive data sequence Pr2 {Pr2(2)} are output directly. Therefore, adder 710—that is, data generation apparatus 7—can add second receive data sequence Pr2 {Pr2(0)} multiplied by high weighting coefficient W2 with a high likelihood, generate a second decoding data sequence Pd2 {Pd2(0), Pr1(1), Pr2(2)}, and output this second decoding data sequence Pd2.

As with first decoding data sequence Pd1, this second decoding data sequence Pd2 is decoded by Viterbi decoder 8 shown in FIG. 2, and a cyclic redundancy check is performed on this decoded packet communication data by CRC decoder 9. If the result of the cyclic redundancy check is that the packet communication data has not been decoded correctly and an error has occurred, receiver 2 again sends an HARQ to transmitter 1. Thereafter, the same processing is executed repeatedly until an error does not occur as a result of a cyclic redundancy check.

Thus, according to Embodiment 1, reception qualities Q1 and Q2 of first receive data sequence Pr1 and second receive data sequence Pr2 are measured, first receive data sequence Pr1 and second receive data sequence Pr2 are weighted according to their reception quality, and second decoding data sequence Pd2 can be generated from weighted first receive data sequence Pr1 and second receive data sequence Pr2, enabling a second decoding data sequence Pd2 that can be correctly decoded to be generated. It is therefore possible to implement a receiver 2 that enables reception performance to be improved in a packet communication system that uses the HARQ method, and a radio communication system that includes this receiver 2.

### Embodiment 2

In Embodiment 2 of the present invention, a modified example of data generation apparatus 7 of receiver 2 in a radio communication system according to Embodiment 1 is described.

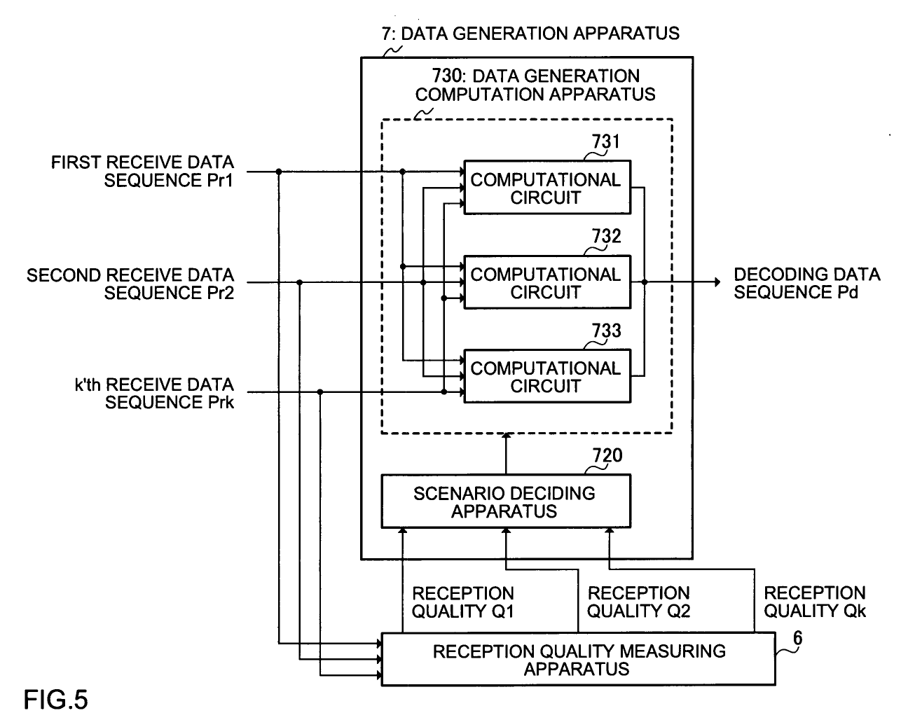

As shown in FIG. 5, receiver 2 in a radio communication system according to Embodiment 2 is equipped with a reception quality measuring apparatus 6 that measures reception qualities Q1, Q2, and Qk of a first receive data sequence Pr1 that failed to be decoded, and a second receive data sequence Pr2 and k'th receive data sequence Prk retransmitted based-on an automatic repeat request; and a data generation apparatus 7 that generates a decoding data sequence Pd based on first receive data sequence Pr1, second receive data sequence Pr2, and k'th receive data sequence Prk; wherein data generation apparatus 7 has a data generation computation apparatus (data generation computation section) 730 in which are installed by condition a plurality of computational circuits 731 through 733 that generate a decoding data sequence Pd based on first receive data sequence Pr1, second receive data sequence Pr2, and k'th receive data sequence Prk; and a scenario deciding apparatus (scenario deciding section) 720 that decides on a scenario for selecting one of computational circuits 731 through 733 of data generation computation apparatus 730 based on reception quality Q. Except for this data generation apparatus 7, the configuration of receiver 2 according to Embodiment 2 is identical to the configuration of receiver 2 according to Embodiment 1.

A brief description will now be given of the operation of above-mentioned data generation apparatus 7 of receiver 2. When, for example, first receive data sequence Pr1 is input to receiver 2, this first receive data sequence Pr1 is input both to data generation apparatus 7 and to reception quality measuring apparatus 6.

In reception quality measuring apparatus 6, reception quality Q1 of first receive data sequence Pr1 is measured. This reception quality Q1 is output to scenario deciding apparatus 720, which selects, according to reception quality Q1, one of computational circuits 731 through 733 of data generation computation apparatus 730 that is capable of generating a decoding data sequence Pd that can be decoded correctly.

First receive data sequence Pr1 that has been input to data generation apparatus 7 passes through the selected one of computational circuits 731 through 733 of data generation computation apparatus 730, and a decoding data sequence Pd that can be decoded correctly can be generated.

As described in the explanation of the operation of receiver 2 according to Embodiment 1 given earlier, this decoding data sequence Pd is decoded by Viterbi decoder 8 shown in FIG. 2, and a cyclic redundancy check is performed on this decoded packet communication data by CRC decoder 9. If the result of the cyclic redundancy check is that the packet communication data has not been decoded correctly and an error has occurred, receiver 2 sends an HARQ to transmitter 1. Thereafter, the same processing is executed repeatedly until an error does not occur as a result of a cyclic redundancy check.

Thus, according to Embodiment 2, a scenario is decided on that applies to reception qualities Q1 through Qk of first receive data sequence Pr1, second receive data sequence Pr2, and k'th receive data sequence Prk, respectively, and computational processing is performed by passage through one of computational circuits 731 through 733 that is in line with this scenario, thereby enabling a decoding data sequence Pd that can be decoded correctly to be generated.

As described above, according to the present invention, it is possible to provide a decoding apparatus and communication system receiver that enable reception performance to be improved in a packet communication system in which the HARQ method is used.

That is to say, a decoding apparatus of the present invention has a configuration equipped with a reception quality measuring section that measures the reception quality of a first receive data sequence that failed to be decoded and a second receive data sequence retransmitted based on an HARQ; a weighting section that compares the reception qualities of the first receive data sequence and the second receive data sequence, performs high weighting for the one with the higher reception quality, and performs low weighting for the one with the lower reception quality; and a data generation section that generates a decoding data sequence in accordance with weighting based on the weighted first receive data sequence and second receive data sequence.

According to this configuration, the reception qualities of a first receive data sequence and second receive data sequence are measured, the first receive data sequence and second receive data sequence are weighted according to their reception quality, and a decoding data sequence can be generated from the weighted first receive data sequence and second receive data sequence, enabling a decoding data sequence that can be correctly decoded to be generated.

A decoding apparatus of the present invention has a configuration in which the above-described reception quality measuring section estimates channel quality (SNR) from a training sequence known signal included in the first receive data sequence and the second receive data sequence.

According to this configuration, the reception quality measuring section can measure reception quality by means of channel quality for the first receive data sequence and second receive data sequence.

A decoding apparatus of the present invention has a configuration in which the above-described reception quality measuring section performs Viterbi decoding processing or Turbo decoding processing on the first receive data sequence and the second receive data sequence, and measures the bit error rate (BER) from the data sequence resulting from decoding the generated received signal.

According to this configuration, the reception quality measuring section can measure reception quality by means of the bit error rate for the first receive data sequence and second receive data sequence.

A decoding apparatus of the present invention has a configuration in which the above-described reception quality measuring section measures RXQUAL (Receiving QUALity) or measures MeanBEP (Mean Bit Error Probability).

According to this configuration, the reception quality measuring section can measure reception quality by means of RXQUAL or MeanBEP for the first receive data sequence and second receive data sequence.

A decoding apparatus of the present invention has a configuration in which the above-described data generation section generates a decoding data sequence from the first receive data sequence and the second receive data sequence based on reception quality measured by the reception quality measuring section.

According to this configuration, the likelihood of whichever of the first receive data sequence or the second receive data sequence has the higher reception quality is made high, and the likelihood of whichever has the lower reception quality is made low, and data destruction due to a receive data sequence of low reception quality can be prevented, enabling a decoding data sequence that can be correctly decoded to be generated.

A decoding apparatus of the present invention has a configuration in which the above-described data generation section is equipped with a coefficient deciding apparatus that decides a weighting coefficient according to reception quality measured by the reception quality measuring apparatus, and a section that generates a decoding data sequence based on the first receive data sequence and second receive data sequence and the weighting coefficient.

According to this configuration, a weighting coefficient is decided based on the reception quality of the first receive data sequence and second receive data sequence, and weighting is applied to the likelihoods of the first receive data sequence and second receive data sequence, enabling a decoding data sequence that can be correctly decoded to be generated.

A decoding apparatus of the present invention has a configuration equipped with a reception quality measuring section that measures the reception quality of a first receive data sequence that failed to be decoded and a second receive data sequence retransmitted based on an automatic repeat request; and a data generation section that generates a decoding data sequence based on the first receive data sequence and second receive data sequence; wherein the data generation section has a data generation computation section in which are installed by condition a plurality of computational circuits that generate a decoding data sequence based on the first receive data sequence and the second receive data sequence; and a scenario deciding section that decides on a scenario for selecting one or another computational circuit of the data generation computation section based on the reception quality.

According to this configuration, a scenario is decided on that applies to reception qualities of the first receive data sequence and second receive data sequence respectively, and computational processing is performed by passage through a computational circuit that is in line with this scenario, thereby enabling a decoding data sequence that can be decoded correctly to be generated.

A communication system receiver of the present invention has a configuration equipped with any one of the above-described decoding apparatuses.

According to this configuration, the decoding apparatus can generate a decoding data sequence that can be decoded correctly based on the reception qualities of a first receive data sequence and a second receive data sequence, enabling the reception quality of a receiver to be improved. Furthermore, as a result of being able to improve receiver reception quality, it is possible to improve the throughput of the entire communication system.

Thus, a decoding apparatus and communication system receiver according to the present invention have an effect of enabling reception quality to be improved, and are effective as a decoding apparatus and communication system receiver that perform generation of decoding data in a mobile communication terminal, mobile communication base station, Bluetooth or optical communication system, or the like.

The present invention is not limited to the above-described embodiments, and various variations and modifications may be possible without departing from the scope of the present invention.

This application is based on Japanese Patent Application No. 2004-125949 filed on Apr. 21, 2004, the entire content of which is expressly incorporated by reference herein.

What is claimed is:

1. A decoding apparatus comprising:
a reception quality measuring section that measures reception quality of a first receive data sequence that failed to be decoded and a second receive data sequence retransmitted based on an automatic repeat request;
a weighting section that compares reception qualities of said first receive data sequence and said second receive data sequence, performs high weighting for one with higher reception quality, and performs low weighting for one with lower reception quality; and
a data generation section that generates a decoding data sequence in accordance with weighting based on weighted said first receive data sequence and said second receive data sequence.

2. The decoding apparatus according to claim 1, wherein said reception quality measuring section estimates channel quality from a training sequence known signal included in said first receive data sequence and said second receive data sequence.

3. The decoding apparatus according to claim 1, wherein said reception quality measuring section performs Viterbi decoding processing or turbo decoding processing on said first receive data sequence and said second receive data sequence, and measures a bit error rate from a data sequence resulting from decoding a generated received signal.

4. The decoding apparatus according to claim 1, wherein said reception quality measuring section measures RXQUAL or measures MeanBEP.

5. The decoding apparatus according to claim 1, wherein said data generation section comprises:
a coefficient deciding apparatus that decides a weighting coefficient according to reception quality measured by said reception quality measuring apparatus; and
a section that generates a decoding data sequence based on said first receive data sequence and second receive data sequence and said weighting coefficient.

6. A decoding apparatus comprising:
a reception quality measuring section that measures reception quality of a first receive data sequence that failed to be decoded and a second receive data sequence retransmitted based on an automatic repeat request; and
a data generation section that generates a decoding data sequence based on said first receive data sequence and second receive data sequence;
wherein said data generation section has:
a data generation computation section in which are installed by condition a plurality of computational circuits that generate a decoding data sequence based on said first receive data sequence and said second receive data sequence; and
a scenario deciding section that decides on a scenario for selecting one or another computational circuit of said data generation computation section based on said reception quality.

7. A communication system receiver comprising the decoding apparatus according to claim 1.
